(19) United States
(12) Patent Application Publication
(10) Pub. No.: US 2024/0321755 A1
(43) Pub. Date: Sep. 26, 2024

(54) SEMICONDUCTOR PACKAGE INCLUDING GLASS CORE SUBSTRATE AND METHOD OF MANUFACTURING THE SAME

(71) Applicant: Samsung Electronics Co., Ltd., Suwon-si (KR)

(72) Inventor: Myungsam Kang, Suwon-si (KR)

(21) Appl. No.: 18/391,844

(22) Filed: Dec. 21, 2023

(30) Foreign Application Priority Data
Mar. 24, 2023 (KR) 10-2023-0039190
May 16, 2023 (KR) 10-2023-0063252

(51) Int. Cl. H01L 23/538; H01L 23/15; H01L 25/065; H10B 80/00

(52) U.S. Cl. CPC H01L 23/5384; H01L 23/15; H01L 23/5381; H01L 23/5383; H01L 25/0652; H01L 25/0657; H10B 80/00; H01L 24/16; H01L 24/32; H01L 24/73; H01L 2224/16145; H01L 2224/16227; H01L 2224/32145; H01L 2224/32225; H01L 2224/73204; H01L 2225/0651; H01L 2225/06562

(57) ABSTRACT

Provided is a semiconductor package capable of minimizing the size of a silicon (Si) interposer and minimizing warpage of a package substrate while maintaining a chip-to-chip connection function. The semiconductor package includes a package substrate including a glass core substrate, a silicon (Si) bridge interposer, and a multi-layer wiring layer disposed under the glass core substrate and the Si bridge interposer, and at least two semiconductor devices stacked on the package substrate, wherein a cavity is formed in a central portion of the glass core substrate, and the Si bridge interposer is embedded in the cavity.

### CROSS-REFERENCE TO RELATED APPLICATIONS

This application is based on and claims priority under 35 U.S.C. § 119 to Korean Patent Application Nos. 10-2023-0039190, filed on Mar. 24, 2023, and 10-2023-0063252, filed on May 16, 2023, in the Korean Intellectual Property Office, the disclosures of which are incorporated by reference herein in their entirety.

### BACKGROUND

The inventive concept relates to a semiconductor package, and more particularly, to a semiconductor package including a glass core substrate.

With the development of the electronics industry, there are increasing demands for high efficiency, high speed, and miniaturization of electronic components. Therefore, there is an increasing need for miniaturization and multi-functionalization of semiconductor chips used in electronic components. Also, the size of semiconductor packages is being reduced based on small semiconductor chips. Also, due to the demand for performance improvement and form factor miniaturization of semiconductor packages, semiconductor packages are employing multi-chip integrated structures. Here, multi-chip integration may refer to integrating chips manufactured through different processes together into a single semiconductor package.

### SUMMARY

Aspects of the inventive concept provide a semiconductor package capable of minimizing the size of a silicon (Si) interposer and minimizing warpage of a package substrate while maintaining a chip-to-chip connection function.

However, the technical goals to be achieved by the inventive concept are not limited to the technical goals mentioned above, and other technical goals may be clearly understood by one of ordinary skill in the art from the following descriptions.

According to an aspect of the inventive concept, a semiconductor package includes a package substrate including a glass core substrate, a semiconductor bridge interposer, and a multi-layer wiring layer disposed under the glass core substrate and the Si bridge interposer, and at least two semiconductor devices stacked on the package substrate, wherein a cavity is formed in a central portion of the glass core substrate, and the semiconductor bridge interposer is embedded in the cavity.

According to another aspect of the inventive concept, a semiconductor package includes a package substrate including a glass core substrate and a multi-layer wiring layer disposed on at least one of a bottom surface and a top surface of the glass core substrate, a semiconductor interposer disposed on the package substrate, and at least two semiconductor devices arranged on the semiconductor interposer.

According to another aspect of the inventive concept, a semiconductor package includes a package substrate including a glass core substrate and a multi-layer wiring layer disposed on at least one of a bottom surface and a top surface of the glass core substrate, a semiconductor interposer disposed within the package substrate or disposed on a top surface of the package substrate, and at least two semiconductor devices arranged on the package substrate or the semiconductor interposer, wherein a cavity is formed in a central portion of the glass core substrate, when the semiconductor interposer is disposed within the package substrate, the semiconductor interposer is disposed in the cavity, and, when the semiconductor interposer is disposed on the top surface of the package substrate, a passive device is disposed in the cavity.

According to another aspect of the inventive concept, a method of manufacturing a semiconductor package includes preparing a glass core substrate having a via electrode therein, placing the glass core substrate within a frame grid, fabricating a package substrate by forming a multi-layer wiring layer on the glass core substrate, and stacking semiconductor devices on the package substrate.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view of a semiconductor package including a glass core substrate, according to an embodiment;

FIGS. 2A to 2C are a perspective view and a cross-sectional view of the glass core substrate in the semiconductor package of FIG. 1 and an enlarged view of a via electrode in the glass core substrate, respectively;

FIGS. 3A and 3B are schematic cross-sectional views of the glass core substrate included in the semiconductor package of FIG. 1;

FIG. 4 is a schematic cross-sectional view of a semiconductor bridge interposer included in the semiconductor package of FIG. 1;

FIGS. 5A to 5C are cross-sectional views of semiconductor devices included in the semiconductor package of FIG. 1;

FIG. 6 is a cross-sectional view of a semiconductor package according to an embodiment;

FIGS. 7A to 7F are schematic cross-sectional views of operations of a method of manufacturing a semiconductor package, according to an embodiment; and

FIGS. 8A to 8F are schematic cross-sectional views of operations of manufacturing a glass core substrate in the method of manufacturing a semiconductor package of FIGS. 7A to 7F.

### DETAILED DESCRIPTION OF THE EMBODIMENTS

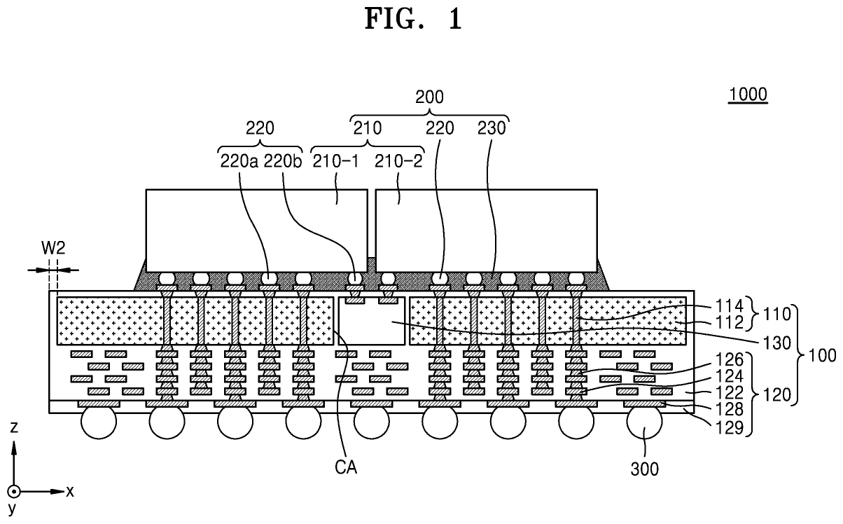

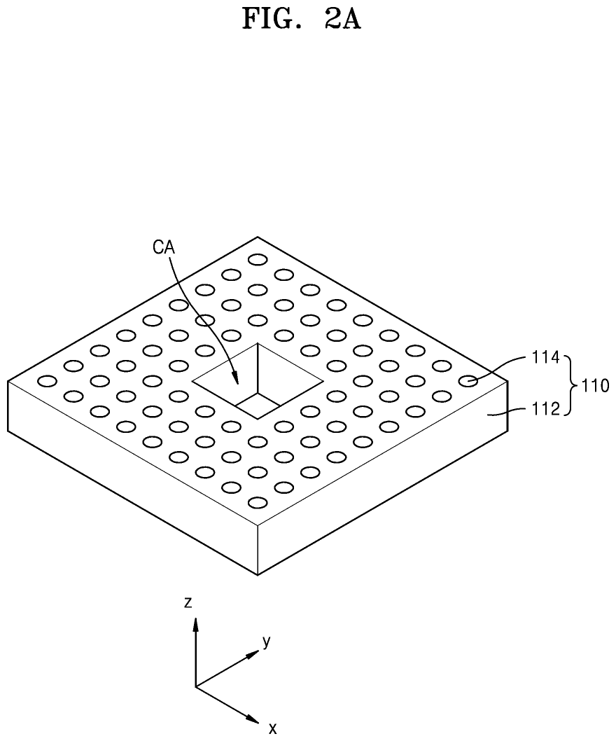

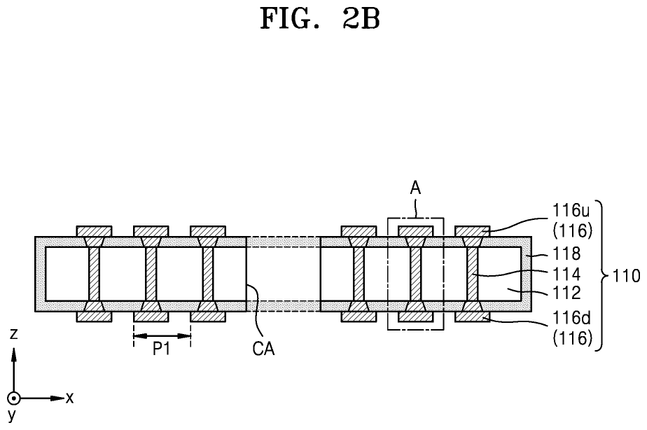

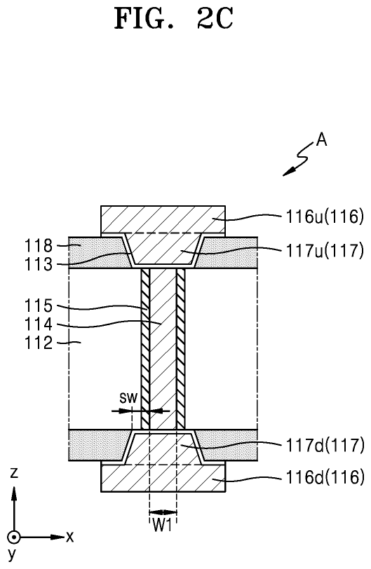

FIG. 1 is a cross-sectional view of a semiconductor package including a glass core substrate, according to an embodiment. FIGS. 2A to 2C are a perspective view and a cross-sectional view of the glass core substrate in the semiconductor package of FIG. 1 and an enlarged view of a via electrode in the glass core substrate, respectively. In addition, FIG. 2A shows only a glass body and a via electrode for convenience of illustration.

Referring to FIGS. 1 to 2C, a semiconductor package 1000 including a glass core substrate according to the present embodiment (hereinafter, simply referred to as a ‘semiconductor package’) may include a package substrate 100 and a package upper structure 200. The package substrate 100 may include a glass core substrate 110, a multi-layer wiring layer 120, and a silicon (Si) bridge interposer 130 (e.g., more generally, a semiconductor bridge interposer). The glass core substrate 110 may include a glass body 112, via electrodes 114, glass pads 116, and a protective layer 118.

The glass body 112 may include or be made of glass. In general, glass exhibits excellent properties like smoothness, desirable thermal expansion coefficient, and surface hardness. For example, glass exhibits excellent smoothness. In this manner, glass may be easily formed wide and flat. Also, glass may exhibit a very low thermal expansion coefficient of 9.0*10-6/° C., and a high hardness from about 6H to about 7H. Furthermore, in the semiconductor package 1000 according to one embodiment, glass used for the glass body 112 of the glass core substrate 110 is tempered glass having increased tensile strength and may exhibit high rigidity.

As shown in FIG. 2A, the glass body 112 may have a rectangular flat panel-like shape. The glass body 112 may have a thickness from about 50 μm to about 1500 μm. However, the thickness of the glass body 112 is not limited to the above-stated numerical range. In the flat panel-like glass body, the glass body 112, the top surface or the bottom surface thereof may correspond to the x-y plane and the thickness-wise direction thereof may correspond to a z direction.

The glass body 112 may include a cavity CA in a central portion. The cavity CA may have a structure penetrating through the glass body 112, for example, devoid of glass material. However, according to embodiments, the cavity CA may not completely penetrate through the glass body 112 and have a groove-like shape in which a portion of the glass body 112 is maintained on the bottom surface of the cavity CA. Therefore, based on different possible embodiments, the cavity CA may be a through hole, or a recess, in the glass body 112. In FIG. 2A, the horizontal cross-section of the cavity CA has a rectangular shape but is not limited thereto. For example, corresponding to the shapes of components arranged in the cavity CA, the horizontal cross-section of the cavity CA may have a circular shape, an elliptical shape, or a polygonal shape other than a rectangular shape.

Each via electrode 114 may have a structure extending in the z direction and penetrating through the glass body 112. One via electrode 114 will be described below, though according to the disclosed embodiments, the description and structure for the example via electrode 114 applies for all via electrodes 114. The top surface and the bottom surface of the via electrode 114 may be exposed on the top surface and the bottom surface of the glass body 112, respectively. The via electrode 114 may have, for example, a cylindrical shape penetrating through the glass body 112. However, the shape of the via electrode 114 is not limited thereto. For example, according to embodiments, the via electrode 114 may have an elliptical columnar shape or a polygonal columnar shape. For reference, since the via electrode 114 has a structure that penetrates through glass, the via electrode 114 may be referred to as a through glass via (TGV).

A first width W1 of the via electrode 114 may be from about 3 μm to about 100 μm. Here, the first width W1 may be defined differently according to the shape of the via electrode 114. For example, when the via electrode 114 has a cylindrical shape, the first width W1 thereof may correspond to the diameter of a circle. Also, when the via electrode 114 has an elliptical columnar shape, the first width W1 thereof may correspond to the major axis of an ellipse. When the via electrode 114 has a polygonal columnar shape, the first width W1 thereof may correspond to a diagonal of a polygon, any one side of the polygon, or the height of the polygon. A maximum first width W1 refers to a maximum horizontal width for the via electrode 114, regardless of the cross-sectional shape along the x-y plane.

As shown in FIG. 2A, the via electrodes 114 may be disposed in a 2-dimensional array structure within the glass body 112 except the cavity CA. In the semiconductor package 1000 according to the present embodiment, signal integrity (SI) performance may be improved by minimizing the pitch of the via electrodes 114 in the glass core substrate 110. For example, the via electrodes 114 may have a first pitch PI of 100 μm. However, the first pitch PI of the via electrodes 114 is not limited to 100 μm.

The via electrodes 114 may include or be formed of a metal, a conductive metal oxide, a conductive metal nitride, etc. For example, each via electrode 114 may be one or more of copper (Cu), tungsten (W), aluminum (Al), nickel (Ni), cobalt (Co), titanium (Ti), titanium nitride (TIN), etc. In detail, in the semiconductor package 1000 according to the present embodiment, the via electrodes 114 of the glass core substrate 110 may be formed of Cu. The via electrodes 114 may be formed through, for example, electroplating. However, the inventive concept is not limited thereto, and the via electrodes 114 may be formed through a different process such as deposition or sputtering.

Moreover, side surfaces of each via electrode 114 may be surrounded by an adhesive layer 115. The adhesive layer 115 may firmly couple the via electrode 114 and the glass body 112 to each other. The adhesive layer 115 may be or include a conductive material or a non-conductive material. For example, the adhesive layer 115 may be or include Ni, tin (Sn), Ti, titanium tungsten (TiW), silicon nitride (SiN), etc. However, the material constituting the adhesive layer 115 is not limited to the above-stated materials. The adhesive layer 115 may have a thickness that is less than 1 μm. However, the thickness of the adhesive layer 115 is not limited to be less than 1 μm.

The glass pads 116 may include upper glass pads 116u and lower glass pads 116d. The glass pads may be formed on the glass body 112 of an electrically conductive material (e.g., not glass-they are referred to as glass pads for being formed on the glass substrate and for passing signals or voltage to and from conductive components in the glass substrate). For example, in one embodiment, the glass pads 116 may be formed of or may include the same material as the via electrodes 114. For example, the glass pads 116 may be or may include Cu, W, Al, Ni, Co, Ti, TiN, etc. In detail, in the semiconductor package 1000 according to one embodiment, the glass pads 116 of the glass core substrate 110 may be Cu pads. The glass pads may have a flat outer surface that has, for example, a circular shape from a top-down view.

In addition, the glass pads 116 may be connected to the via electrodes 114 through vias 117. The vias 117 may include upper vias 117u and lower vias 117d, like the glass pads 116. Also, the vias 117 may include or be formed of the same material as the via electrodes 114. For example, the via 117 may include or be formed of Cu, W, Al, Ni, Co, Ti, TiN, etc. In detail, in the semiconductor package 1000 according to one embodiment, the vias 117 of the glass core substrate 110 may be Cu vias.

In the semiconductor package 1000 according to some embodiments, each glass pad 116 and corresponding via 117 may be formed together. For example, the glass pad 116 and the via 117 may be formed together through electroplating by using a seed layer 113 formed on the via electrode 114 and the protective layer 118. Therefore, although the glass pad 116 and the via 117 are distinguished by a solid line in FIG. 1 or 2B, the glass pad 116 and the via 117 may be actually integrated into one body. Therefore, in FIG. 2C, the glass pad 116 and the via 117 are distinguished by a dashed line. According to some embodiments, the glass pad 116 and the via 117 are not distinguished as separate components but treated as one component and may be collectively referred to as a ‘pad’ or a ‘via pad’.

The glass pad 116 may have a circular or rectangular flat panel-like shape. Therefore, a vertical cross-section of the glass pad 116 may have a rectangular shape that is elongated in the x direction or the y direction. The bottom surface, or more generally, the bottom, or bottom interface of the upper glass pad 116u may be coupled to the upper via 117u, and an upper connection terminal 220, such as a bump or a solder, may be disposed on the top surface of the upper glass pad 116u. The top surface, or more generally, the top, or top interface of the lower glass pad 116d may be coupled to the lower via 117d, and the bottom surface of the upper glass pad 116u may be connected to a vertical via 126 of the multi-layer wiring layer 120. Also, the glass pad 116 may extend in a horizontal direction from the top surface (or more generally top, or top interface) or the bottom surface (or more generally bottom, or bottom interface) of the via 117 onto the top surface or the bottom surface of the protective layer 118.

The via 117 may be disposed between the glass pad 116 and the via electrode 114. For example, the via 117 may penetrate through the protective layer 118 and connect the glass pad 116 and the via electrode 114 to each other. The via 117 may have a truncated cone-like shape, an inverted truncated cone-like shape, a quadrangular truncated shape, or an inverted quadrangular truncated shape. Therefore, the vertical cross-section of the via 117 may have, for example, a trapezoidal or inverted trapezoidal shape.

In addition, the size of the via 117 may be larger than that of the via electrode 114. Here, size may refer to a planar area. For example, the area of the bottom surface or the top surface of the via 117 may be larger than the area of the top surface or the bottom surface of the via electrode 114 connected to the via 117. For example, when the via electrode 114 and the lower via 117d are precisely aligned and coupled to each other in the z direction and a distance between an end of the via electrode 114 and an end of the top surface of the lower via 117d in the x direction is referred to as one side length SW, the one side length SW may be from about 5 μm to about 30 μm. However, the one side length SW between the via electrode 114 and the lower via 117d is not limited to the above-stated numerical range. As the via 117 is formed to be larger than the via electrode 114, the via electrode 114 and the via 117 may be easily aligned with one another, and thus, misalignment between the via electrode 114 and the glass pad 116 may be minimized.

The protective layer 118 may cover an outer surface of the glass body 112. The protective layer 118 may protect the glass body 112 and the via electrode 114. The protective layer 118 may include or be an electrically-insulating material such as an epoxy resin or an adhesive film. For example, in the semiconductor package 1000 according to one embodiment, the protective layer 118 of the glass core substrate 110 may be Ajinomoto Build-up Film (ABF) resin. However, the material constituting the protective layer 118 is not limited to ABF resin.

The multi-layer wiring layer 120 may include an insulation body 122, wiring lines 124, vertical vias 126, substrate pads 128, and a substrate protection layer 129. The insulation body 122 may include or be an insulation material. In the semiconductor package 1000 according to the present embodiment, the insulation body 122 of the multi-layer wiring layer 120 may be ABF resin. However, the material constituting the insulation body 122 is not limited to ABF resin. For example, the insulation body 122 may be or include polyimide (PI) resin, photo imageable dielectric (PID) resin, or prepreg. The insulation body 122 may have a multi-layer structure according to the multi-layer structure of the wiring lines 124. However, in FIG. 1, for convenience of illustration, the insulation body 122 is shown as a single layer structure.

The wiring lines 124 may have a multi-layer structure. Wiring lines 124 of different layers may be connected to each other by the vertical vias 126. The wiring lines 124 and the vertical vias 126 may include or be formed of Cu. However, the material constituting the wiring line 124 and the vertical via 126 is not limited to Cu.

The substrate pad 128 may be disposed on the bottom surface of the insulation body 122. The bottom surface of the insulation body 122 is covered by the substrate protection layer 129, and the substrate pad 128, formed of an electrically-conductive material, may be disposed in a structure penetrating through the substrate protection layer 129. The bottom surface of the substrate pad 128 may be exposed to the outside from the substrate protection layer 129. An external connection terminal 300 may be disposed on the bottom surface of the substrate pad 128. The external connection terminal 300 may be electrically connected to semiconductor devices 210 through wiring lines 124 of the multi-layer wiring layer 120, the via electrode 114 of the glass core substrate 110, and the upper connection terminal 220. The external connection terminal may be, for example, a solder ball or other conductive terminal.

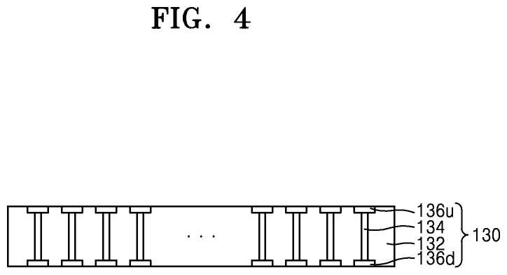

The Si bridge interposer 130 may be disposed inside the cavity CA of the glass core substrate 110. The Si bridge interposer 130 may connect at least two semiconductor devices 210 arranged on the package substrate 100 to each other. The Si bridge interposer 130 may include or be formed of an Si body (refer to 132 of FIG. 4) and via electrodes (refer to 134 of FIG. 4). The structure of the Si bridge interposer 130 is described below in more detail with reference to FIG. 4.

As shown in FIG. 1, the glass core substrate 110 including the Si bridge interposer 130 may have a structure disposed within the package substrate 100. For example, the insulation body 122 of the multi-layer wiring layer 120 may cover the bottom surface and side surfaces of the glass core substrate 110 and may also cover the bottom surface of the Si bridge interposer 130. Therefore, the side surfaces of the glass core substrate 110 may not be exposed to the outside. For example, in the x direction or the y direction, a second width W2 between an end of a side surface of the glass core substrate 110 and an end of the insulation body 122 corresponding thereto may be from about 30 μm to about 500 μm. However, the second width W2 between the end of the side surface of the glass core substrate 110 and the end of the insulation body 122 corresponding thereto is not limited to the above-stated numerical range.

The wiring lines 124 of the multi-layer wiring layer 120 may be arranged under the Si bridge interposer 130 and the glass core substrate 110. Also, the wiring lines 124 may be connected to the via electrodes 114 of the glass core substrate 110 and the via electrodes 134 of the Si bridge interposer 130. Therefore, the via electrodes 114 of the glass core substrate 110 may be connected to the external connection terminals 300 through the wiring lines 124. Also, the via electrodes 134 of the Si bridge interposer 130 may be connected to the external connection terminals 300 and/or the via electrodes 134 adjacent thereto through the wiring lines 124.

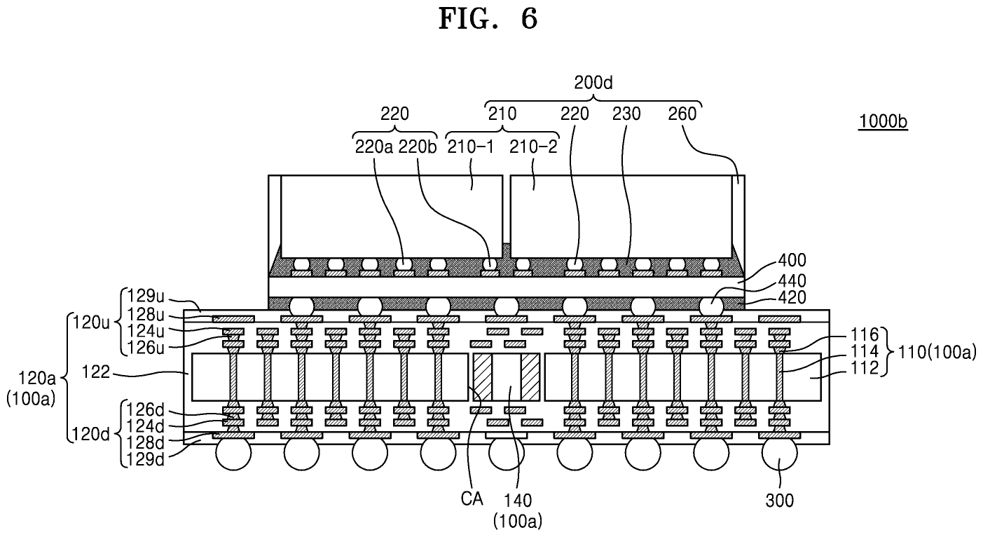

In the semiconductor package 1000 according to the present embodiment, the glass core substrate 110 may be disposed in an upper portion of the package substrate 100 in the vertical direction, that is, the z direction. Therefore, the glass core substrate 110 may be disposed within the package substrate 100 in a structure asymmetrical in the z direction. However, according to some embodiments, the glass core substrate 110 may be disposed within the package substrate 100 in a structure symmetrical in the z direction. The symmetrical structure of the glass core substrate 110 is described later in more detail in the description of a semiconductor package 1000b of FIG. 6.

The package upper structure 200 may include at least two semiconductor devices 210, the upper connection terminals 220, and an underfill 230. The at least two semiconductor devices 210 may each have a single chip structure. However, the inventive concept is not limited thereto, and at least one of the at least two semiconductor devices 210 may have a package structure including a plurality of semiconductor chips.

The at least two semiconductor devices 210 may include, for example, a first semiconductor device 210-1 and a second semiconductor device 210-2. However, the number of semiconductor devices included in the at least two semiconductor devices 210 is not limited to two. For example, the at least two semiconductor devices 210 may include three or more semiconductor devices. As shown in FIG. 1, the first semiconductor device 210-1 and the second semiconductor device 210-2 may be arranged adjacent to each other on the package substrate 100. However, according to some embodiments, the first semiconductor device 210-1 and the second semiconductor device 210-2 may be arranged on the package substrate 100 in a stacked structure.

The at least two semiconductor devices 210 may each include a logic chip and/or a memory chip. A logic chip may be an application processor (AP), a microprocessor, a central processing unit (CPU), a controller, an application specific integrated circuit (ASIC), etc. Also, a logic chip of any one of the at least two semiconductor devices 210 may constitute an AP/GPU/CPU/SOC chip, etc. Also, a logic chip of any one of the at least two semiconductor devices 210 may constitute a modem chip supporting communication of an AP/GPU/CPU/SOC chip, etc. Depending on the types of logic chips, the semiconductor package 1000 may be classified as a server-oriented semiconductor device or a mobile-oriented semiconductor device. A memory chip may be or include, for example, a volatile memory device like dynamic random access memory (DRAM) and static random access memory (SRAM) or a non-volatile memory device such as flash memory.

The at least two semiconductor devices 210 may be stacked on the package substrate 100 through the upper connection terminals 220. The upper connection terminals 220 may be, for example, conductive bumps such as solder bumps and may include first upper connection terminals 220a connected to the via electrodes 114 of the glass core substrate 110 and second upper connection terminals 220b connected to the via electrodes 134 of the Si bridge interposer 130. The underfill 230 may fill a space between the at least two semiconductor devices 210 and the package substrate 100 and between upper connection terminals 220.

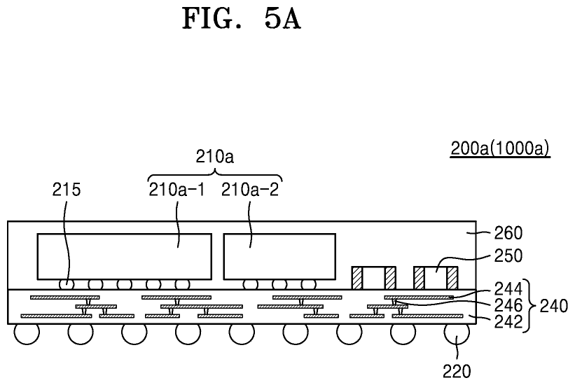

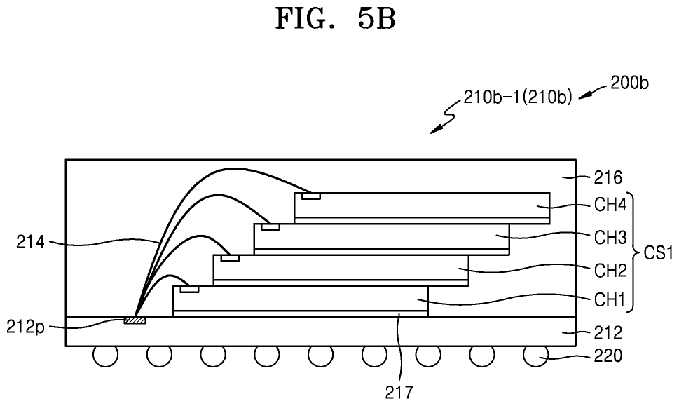

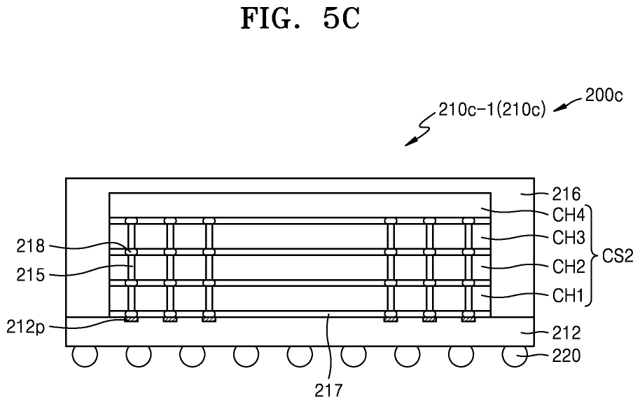

The upper package structure 200 may have a package structure in which the at least two semiconductor devices 210 are sealed together. However, the inventive concept is not limited thereto, and the at least two semiconductor devices 210 may each have a package structure in the package upper structure 200. The package structure of the package upper structure 200 is described below in more detail with reference to FIG. 5A, and the package structure of each of the at least two semiconductor devices 210 is described below in more detail with reference to FIGS. 5B and 5C.

In the semiconductor package 1000 according to the present embodiment, the package substrate 100 may include the glass core substrate 110 embedded therein. Also, as the Si bridge interposer 130 is disposed in the cavity CA of the glass core substrate 110, the Si bridge interposer 130 may be embedded in the package substrate 100. Due to the structure of the package substrate 100, the size of the Si bridge interposer 130 may be minimized while maintaining a chip-to-chip connection function through the Si bridge interposer 130. Therefore, in a 2.5D package for high performance computing (HPC), the issue of increased cost due to the large area of an Si interposer may be avoided. Also, warpage of the package substrate 100 may be minimized due to the low thermal expansion coefficient and high rigidity of the glass core substrate 110. Furthermore, SI performance may be improved by minimizing the pitch of the via electrodes 114 in the glass core substrate 110, and parasitic inductance may be reduced by reducing the sizes of the via electrodes 114 and the vias 117. By increasing the size of the vias 117 connected to the via electrodes 114, misalignment between the via electrodes 114 and the glass pads 116 may be minimized.

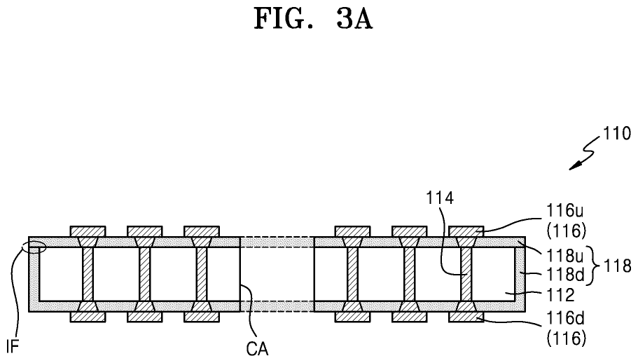

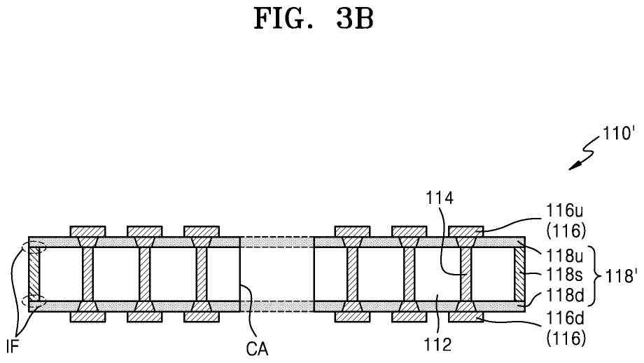

FIGS. 3A and 3B are schematic cross-sectional views of the glass core substrate included in the semiconductor package of FIG. 1. Descriptions already given above with reference to FIGS. 1 to 2C are briefly given or omitted.

Referring to FIG. 3A, in the semiconductor package 1000 according to one embodiment, the glass core substrate 110 of the package substrate 100 may include the glass body 112, the via electrodes 114, the glass pads 116, and the protective layer 118. The glass body 112, the via electrodes 114, and the glass pads 116 are identical to those described above in the description of FIGS. 1 to 2C.

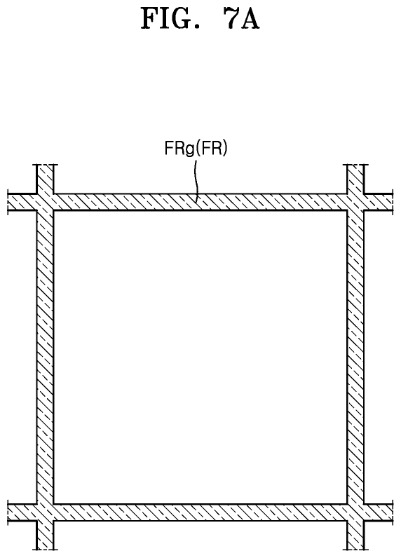

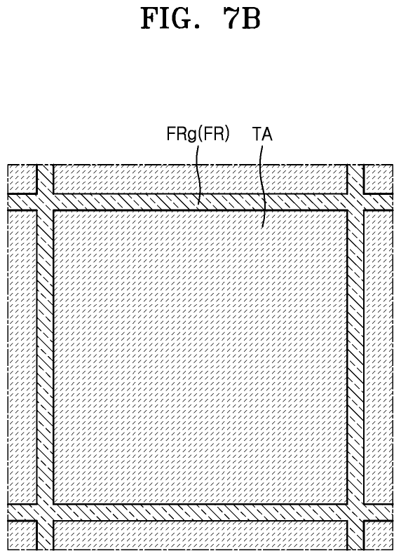

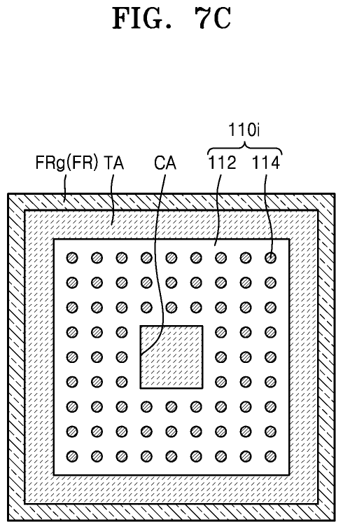

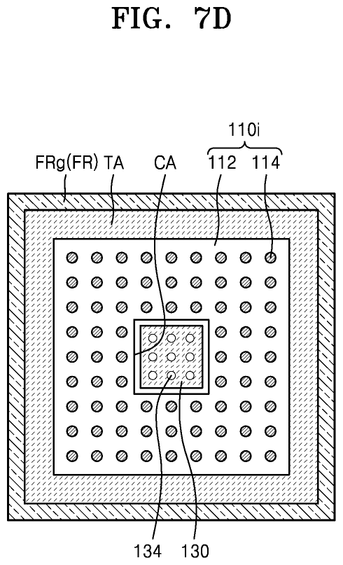

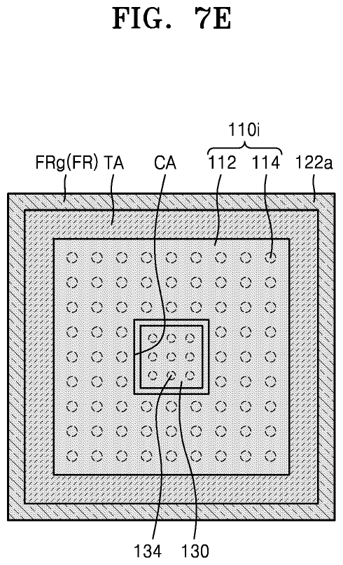

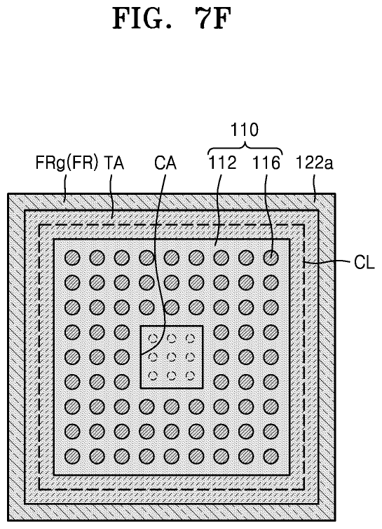

As shown in the drawings, the protective layer 118 may surround the outer surface of the glass body 112. The protective layer 118 may entirely include the same material. For example, the protective layer 118 may be ABF resin. However, the material constituting the protective layer 118 is not limited to ABF resin. The protective layer 118 may include an upper protective layer 118u disposed on the top surface of the glass body 112 and a lower protective layer 118d disposed on the bottom surface and side surfaces of the glass body 112. Also, there may be an interface IF at a junction between the upper protective layer 118u and the lower protective layer 118d. In detail, as shown in FIG. 3A, the interface IF may be formed at a junction between an outer portion of the upper protective layer 118u and side portion of the lower protective layer 118d. Also, the interface IF may be clearly distinguished in the glass core substrate 110. The reason why the interface IF is formed in the protective layer 118 may be that the protective layer 118 is not entirely formed at once and the upper protective layer 118u and the lower protective layer 118d are formed separately with a time interval therebetween. The formation of the protective layer 118 is described below in more detail in the description of a method of manufacturing a semiconductor package of FIGS. 7A to 7F.

Referring to FIG. 3B, in the semiconductor package 1000 according to one embodiment, a glass core substrate 110′ of the package substrate 100 may be different from the glass core substrate 110 of the package substrate 100 of the semiconductor package 1000 of FIG. 3A for a protective layer 118′. In detail, the glass core substrate 110′ may include the glass body 112, the via electrodes 114, the glass pads 116, and the protective layer 118′. The glass body 112, the via electrodes 114, and the glass pads 116 are identical to those described above in the description of FIGS. 1 to 2C.

Like the protective layer 118 in FIG. 3A, the protective layer 118′ may surround the outer surface of the glass body 112. However, in the glass core substrate 110′ according to the present embodiment, side portion of the protective layer 118′ may include a different material. In detail, the protective layer 118′ may include the upper protective layer 118u disposed on the top surface of the glass body 112, the lower protective layer 118d disposed on the bottom surface of the glass body 112, and a side protection layer 118s disposed on side surfaces of the glass body 112. The upper protective layer 118u and the lower protective layer 118d may be or include, for example, ABF resin, and the side protection layer 118s may be or include a polymer based on polyimide (PI), polybenzoxazole (PBO), polyhydroxystyrene (PHS), epoxy, benzocyclobutene (BCB), etc. Also, the side protection layer 118s may exhibit high filling characteristics by including silica of various sizes. However, the materials constituting the upper protective layer 118u, the lower protective layer 118d, and the side protection layer 118s are not limited to the above-stated materials.

Also, in the glass core substrate 110 according to the present embodiment, there may be interfaces IF at a junction between the upper protective layer 118u and the side protection layer 118s and a junction between the side protection layer 118s and the lower protective layer 118d. This interface IF may be formed because the type of a material constituting the upper protective layer 118u and the lower protective layer 118d is different from the type of a material constituting the side protection layer 118s. Also, the interface IF may be formed because the upper protective layer 118u, the lower protective layer 118d, and the side protection layer 118s are separately formed.

FIG. 4 is a schematic cross-sectional view of an Si bridge interposer included in the semiconductor package of FIG. 1. Descriptions are given below with reference to FIG. 1, and descriptions already given above with reference to FIGS. 1 to 2C are briefly given or omitted.

Referring to FIG. 4, the Si bridge interposer 130 may be disposed in the cavity CA of the glass core substrate 110 as shown in FIG. 1. The Si bridge interposer 130 may include a silicon body 132, via electrodes 134, and interposer pads 136. The silicon body 132 may have a rectangular flat panel-like shape. However, the shape of the silicon body 132 is not limited to the rectangular flat panel-like shape. For example, the silicon body 132 may have a shape of a circular flat panel or a polygonal flat panel other than a rectangular flat panel.

Each via electrode 134 may extend through the silicon body 132. The via electrode 134 may have a cylindrical shape or a polygonal columnar shape. The via electrode 134 may include a central metal layer and a protective layer (e.g., an electrically-insulating layer) surrounding the central metal layer. Also, the via electrode 134 may include a barrier metal layer between the central metal layer and the protective layer. Since the via electrode 134 penetrates through Si, the via electrode 134 may be referred to as a through silicon via (TSV).

The interposer pads 136 may include upper interposer pads 136u on the top surface of the silicon body 132 and a lower interposer pads 136d on the bottom surface of the silicon body 132. The via electrodes 134 may directly interconnect the upper interposer pads 136u and the lower interposer pads 136d. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

In the semiconductor package 1000 according to the present embodiment, the Si bridge interposer 130 may be disposed in the cavity CA of the glass core substrate 110 as shown in FIG. 1. Therefore, signals may be transmitted between the at least two semiconductor devices 210 through a short path by using the Si bridge interposer 130 in the package substrate 100 and the wiring lines 124 of the multi-layer wiring layer 120. Also, signal transmission between the at least two semiconductor devices 210 and the external connection terminals 300 for signal transmission from/to the outside may also be performed through a short path by using the glass core substrate 110 in the package substrate 100 and the wiring lines 124 of the multi-layer wiring layer 120.

FIGS. 5A to 5C are cross-sectional views of semiconductor devices included in the semiconductor package of FIG. 1. Descriptions of FIGS. 5A to 5C are given below with reference to FIG. 1, and descriptions already given above with reference to FIGS. 1 to 4 are briefly given or omitted.

Referring to FIG. 5A, a semiconductor package 1000a according to the present embodiment may be different from the semiconductor package 1000 of FIG. 1 for a package upper structure 200a. In detail, the semiconductor package 1000a of the present embodiment may include the package substrate 100 and the package upper structure 200a. The package upper structure 200a may have a package structure in which at least two semiconductor devices 210a are sealed together by a sealing member 260. In detail, the package upper structure 200a may include the at least two semiconductor devices 210a, the upper connection terminals 220, the underfill 230, an upper package substrate 240, a passive device 250, and the sealing member 260.

The at least two semiconductor devices 210a may include, for example, a first semiconductor device 210a-1 and a second semiconductor device 210a-2. However, the number of semiconductor devices included in the at least two semiconductor devices 210a is not limited to two. The at least two semiconductor devices 210a may be functionally similar to the at least two semiconductor devices 210 of the semiconductor package 1000 of FIG. 1. For example, the at least two semiconductor devices 210a may each include a logic chip and/or a memory chip. As shown in FIG. 5A, at least one of the at least two semiconductor devices 210a may have a different size from the other(s). However, according to some embodiments, all of the at least two semiconductor devices 210a may have the same size.

The upper package substrate 240 may include an upper body 242, an upper wiring line 244, and upper vertical vias 246. The upper body 242 may include or be a polymer layer. For example, the upper body 242 may include PID resin and may further include an inorganic filler. However, the materials constituting the upper body 242 are not limited to the above-stated materials. The upper body 242 may have a multi-layer structure according to the multi-layer structure of the upper wiring line 244. First substrate pads may be arranged on the top surface and the bottom surface of the upper body 242. For example, upper connection terminals 220 may be arranged on first substrate pads on the bottom surface of the upper body 242, and bumps 215 of the semiconductor devices 210a may be arranged on first substrate pads on the top surface of the upper body 242. A first substrate pad on the top surface of the upper body 242 and a first substrate pad on the bottom surface of the upper body 242 may be connected to each other through the upper wiring line 244 and the upper vertical via 246.

The at least two semiconductor devices 210a may be arranged on the upper package substrate 240 through the bumps 215. According to some embodiments, the at least two semiconductor devices 210a may also be arranged on the upper package substrate 240 through wires instead of the bumps 215. Also, the at least two semiconductor devices 210a may have a stacked structure and be arranged on the upper package substrate 240. When the at least two semiconductor devices 210a have a stacked structure and are arranged on the upper package substrate 240 by using wires, the at least two semiconductor devices 210a may be stacked in a stepped structure or a zigzag structure.

The passive device 250 may include 2-terminal devices such as a resistor, a capacitor, and an inductor. In FIG. 5A, two passive devices 250 are arranged on the upper package substrate 240. However, the number of passive devices 250 arranged on the upper package substrate 240 is not limited to two. Also, according to some embodiments, the passive devices 250 may be arranged not only on the top surface of the upper package substrate 240 but also on the bottom surface, or inside of the package substrate 100.

The sealing member 260 may seal the at least two semiconductor devices 210a and the passive devices 250. The sealing member 260 may protect the at least two semiconductor devices 210a and the passive devices 250 from physical or chemical damage from the outside. Also, the sealing member 260 may fill a space between the at least two semiconductor devices 210a and the upper package substrate 240 and spaces between the bumps 215. According to some embodiments, an internal underfill may fill the space between the at least two semiconductor devices 210a and the upper package substrate 240 and the spaces between the bumps 215, and the sealing member 260 may cover the internal underfill and the at least two semiconductor devices 210a.

The sealing member 260, also described as an encapsulation layer, may be or include an insulating material, e.g., a thermosetting resin such as an epoxy resin or a thermoplastic resin such as polyimide. Also, the sealing member 260 may be or include a thermosetting resin or a thermoplastic resin including a reinforcing material like an inorganic filler. In detail, the sealing member 260 may be or include ABF, FR-4, BT resin, etc. Also, the sealing member 260 may be or include a molding material such as EMC or a photosensitive material such as photo-imageable encapsulant (PIE). Of course, the material of the sealing member 260 is not limited to the above-stated materials.

Referring to FIG. 5B, the semiconductor package 1000 of the present embodiment may be different from the semiconductor package 1000 of FIG. 1, in that at least one of at least two semiconductor devices 210b of a package upper structure 200b has a package structure. In detail, like the semiconductor package 1000 of FIG. 1, the semiconductor package 1000 according to the present embodiment may include the package substrate 100 and the package upper structure 200b. The package upper structure 200b may include the at least two semiconductor devices 210b, the upper connection terminals 220, and the underfill 230 (not shown in FIG. 5B). The upper connection terminals 220 and the underfill 230 are identical to those described above in the description of the semiconductor package 1000 of FIG. 1.

As shown in FIG. 5B, at least one of the at least two semiconductor devices 210b, e.g., a first semiconductor device 210b-1, may have a package structure in which a plurality of semiconductor chips CH1 to CH4 are sealed together by an upper sealing member 216. In detail, the first semiconductor device 210b-1 may include a first package substrate 212, a first chip stack structure CS1, and the upper sealing member 216.

The first package substrate 212 may include or be formed of, for example, silicon, glass, ceramic, or plastic. The first package substrate 212 may include wiring lines having a single layer structure or a multiple layer structure. First upper substrate pads 212p may be disposed on the top surface of the first package substrate 212. Also, although not shown, first lower substrate pads may be disposed on the bottom surface of the first package substrate 212, and the upper connection terminals 220 may be disposed on the first lower substrate pads.

The first chip stack structure CS1 may be stacked on the first package substrate 212 and electrically connected to the first package substrate 212 through a wire 214. In detail, a first semiconductor chip CH1 may be stacked on the first package substrate 212 through an adhesive layer 217, and the second semiconductor chip CH2 may be stacked on the first semiconductor chip CH1 through the adhesive layer 217. In this regard, four semiconductor chips CH1 to CH4 may be stacked on the first package substrate 212. Also, all of the four semiconductor chips CH1 to CH4 may be connected to the first package substrate 212 through wires 214. Accordingly, chip pads of the semiconductor chips CH1 to CH4 may be electrically connected to first upper substrate pads 212p of the first package substrate 212 through the wires 214. Therefore, the top surface of each of the four semiconductor chips CH1 to CH4 may correspond to an active surface, and the bottom surface of each of the four semiconductor chips CH1 to CH4 may correspond to an inactive surface.

The first chip stack structure CS1 may include the four semiconductor chips CH1 to CH4, e.g., the first semiconductor chip CH1, a second semiconductor chip CH2, a third semiconductor chip CH3, and a fourth semiconductor chip CH4. However, the number of semiconductor chips included in the first chip stack structure CS1 is not limited to four, and the first chip stack structure CS1 may include two or more semiconductor chips. As shown in FIG. 5B, in the first chip stack structure CS1 of the first semiconductor device 210b-1, the four semiconductor chips CH1 to CH4 may be stacked in a stepped structure. However, according to some embodiments, the four semiconductor chips CH1 to CH4 may be stacked in a zigzag structure.

In the semiconductor package 1000 according to the present embodiment, the four semiconductor chips CH1 to CH4 of the first semiconductor device 210b-1 may each be or include a memory chip. For example, the four semiconductor chips CH1 to CH4 may each be a DRAM chip. However, the type of the four semiconductor chips CH1 to CH4 is not limited to a memory chip or a DRAM chip.

The upper sealing member 216 may cover the first chip stack structure CS1 to protect the four semiconductor chips CH1 to CH4. Also, the upper sealing member 216 may also cover the top surface of the first package substrate 212 and the wires 214. The upper sealing member 216 may include or be, for example, a silicone-based material, a thermosetting resin, a thermoplastic resin, or a UV treatment material.

Referring to FIG. 5C, the semiconductor package 1000 of the present embodiment may be different from the semiconductor package 1000 of FIG. 1, in that at least one of at least two semiconductor devices 210c of a package upper structure 200c has a package structure. In detail, like the semiconductor package 1000 of FIG. 1, the semiconductor package 1000 according to the present embodiment may include the package substrate 100 and the package upper structure 200c. The package upper structure 200c may include the at least two semiconductor devices 210c, the upper connection terminals 220, and the underfill 230. The upper connection terminals 220 and the underfill 230 are identical to those described above in the description of the semiconductor package 1000 of FIG. 1.

As shown in FIG. 5C, at least one of the at least two semiconductor devices 210c, e.g., a first semiconductor device 210c-1, may have a package structure in which the plurality of semiconductor chips CH1 to CH4 are sealed together by the upper sealing member 216. In detail, the first semiconductor device 210c-1 may include the first package substrate 212, a second chip stack structure CS2, and the upper sealing member 216. The first package substrate 212 and the upper sealing member 216 may have the same types of components as those described above in the description of the first semiconductor device 210b-1 of FIG. 5B. However, the upper sealing member 216 may seal the second chip stack structure CS2 instead of the first chip stack structure CS1.

The second chip stack structure CS2 may be mounted on the first package substrate 212 and electrically connected to the first package substrate 212 through via electrodes 215 and micro bumps 218. The second chip stack structure CS2 may include the four semiconductor chips CH1 to CH4, e.g., the first semiconductor chip CH1, the second semiconductor chip CH2, the third semiconductor chip CH3, and the fourth semiconductor chip CH4. However, the number of semiconductor chips included in the second chip stack structure CS2 is not limited to four, and the second chip stack structure CS2 may include two or more semiconductor chips.

As shown in FIG. 5C, in the second chip stack structure CS2, the first semiconductor chip CH1, the second semiconductor chip CH2, and the third semiconductor chip CH3 may each include the via electrodes 215 therein. Here, the via electrodes 215 may be referred to as a TSV, because it has a structure penetrating through Si of a semiconductor chip. In the case in which the semiconductor chip is not made of silicon, the via electrodes 215 may be referred to as through substrate vias. The uppermost fourth semiconductor chip CH4 may not include a via electrode.

In the semiconductor package 1000 according to the present embodiment, the four semiconductor chips CH1 to CH4 of the first semiconductor device 210c-1 may each include a memory chip. For example, the four semiconductor chips CH1 to CH4 may each be a DRAM chip. However, the type of the four semiconductor chips CH1 to CH4 is not limited to a memory chip or a DRAM chip.

The four semiconductor chips CH1 to CH4 may each be stacked on the first package substrate 212 and a semiconductor chip therebelow through micro bumps 218 and the adhesive layer 217. Also, the four semiconductor chips CH1 to CH4 may each be connected to the first package substrate 212 through the via electrodes 215 and the micro bumps 218 similarly to a flip-chip bonding structure. Therefore, the bottom surface of each of the four semiconductor chips CH1 to CH4 may correspond to an active surface, and the top surface of each of the four semiconductor chips CH1 to CH4 may correspond to an inactive surface.

According to some embodiments, the first semiconductor device 210c-1 may be a high bandwidth memory (HBM) package. When the first semiconductor device 210c-1 is an HBM package, the four semiconductor chips CH1 to CH4 may be stacked on a buffer chip instead of the first package substrate 212. Here, the buffer chip may include a via electrode and a logic device therein. The buffer chip may also be referred to as a logic chip or a control chip. Generally, in an HBM package, memory chips arranged on a buffer chip may be referred to as core chips. Therefore, the four semiconductor chips CH1 to CH4 may correspond to core chips. The buffer chip may be disposed under core chips, integrate signals from the core chips, and transmit integrated signals to the outside and may also transmit signals and power from the outside to the core chips.

FIG. 6 is a cross-sectional view of a semiconductor package according to an embodiment. Descriptions already given above with reference to FIGS. 1 to 5C are briefly given or omitted.

Referring to FIG. 6, a semiconductor package 1000b according to the present embodiment may include a package substrate 100a, a package upper structure 200d, and an Si interposer 400. The package substrate 100a may include the glass core substrate 110, a multi-layer wiring layer 120a, and a passive device 140. The package substrate 100a may be, for example, a high-multi-layer flip-chip ball grid array (FCBGA) substrate. Also, the package substrate 100a may correspond to a structure in which a portion of a copper clad laminated (CCL) core structure of the FCBGA substrate is replaced with the glass core substrate 110.

The glass core substrate 110 is identical to the glass core substrate 110 described above in the descriptions of the semiconductor package 1000 of FIG. 1. However, the glass core substrate 110 may be disposed in a central portion of the package substrate 100a in the z direction. Therefore, the glass core substrate 110 may be disposed in a symmetrical structure within the package substrate 100a. Also, the passive device 140 may be disposed in the cavity CA of the glass core substrate 110 instead of an Si bridge interposer.

The multi-layer wiring layer 120a may include the insulation body 122, an upper multi-layer wiring layer 120u, and a lower multi-layer wiring layer 120d. The insulation body 122 is identical to the insulation body 122 of the multi-layer wiring layer 120 described above in the descriptions of the semiconductor package 1000 of FIG. 1. The upper multi-layer wiring layer 120u may be disposed on the glass core substrate 110 and may include upper wiring lines 124u, upper vertical vias 126u, upper substrate pads 128u, and an upper protective layer 129u. Also, the lower multi-layer wiring layer 120d may be disposed under the glass core substrate 110 and may include lower wiring lines 124d, lower vertical vias 126d, lower substrate pads 128d, and a lower protective layer 129d.

The upper wiring lines 124u and the lower wiring lines 124d may have the same structure as the wiring lines 124 of the multi-layer wiring layer 120 described above in the descriptions of the semiconductor package 1000 of FIG. 1 except locations thereof in the z direction. Also, the upper vertical vias 126u and the lower vertical vias 126d may have the same structure as vertical vias 126 of the multi-layer wiring layer 120 described above in the descriptions of the semiconductor package 1000 of FIG. 1 except locations thereof in the z direction.

The upper substrate pads 128u may be disposed on the top surface of the insulation body 122. The top surface of the insulation body 122 may be covered by the upper protective layer 129u, and the upper substrate pads 128u may be disposed to penetrate through the upper protective layer 129u. The top surface of the upper substrate pads 128u may be exposed to the outside from the upper protective layer 129u. Inter-substrate connection terminals 440 may be disposed on the top surface of the upper substrate pads 128u. The lower substrate pads 128d and the lower protective layer 129d may have the same structure as the substrate pads 128 and the substrate protection layer 129 of the multi-layer wiring layer 120 described above in the descriptions of the semiconductor package 1000 of FIG. 1. However, the external connection terminals 300 on the lower substrate pads 128d may be electrically connected to the semiconductor devices 210 through the lower wiring lines 124d and the upper wiring lines 124u of the multi-layer wiring layer 120a, the via electrodes 114 of the glass core substrate 110, the inter-substrate connection terminals 440, the Si interposer 400, and the upper connection terminals 220.

The passive device 140 may include 2-terminal devices such as a resistor, a capacitor, and an inductor. The passive device 140 may be disposed within a cavity of the glass core substrate 110, as described above. However, according to some embodiments, no cavity may be formed in the glass core substrate 110, and, in such a case, the passive device 140 may be disposed on another portion of the package substrate 100a, e.g., on the top surface, on the bottom surface, or inside the package substrate 100a. Also, the passive device 140 may be disposed on the package upper structure 200d, like the semiconductor package 1000a of FIG. 5A.

The Si interposer 400 may be stacked on the package substrate 100a through inter-substrate connection terminals 440. Also, an external underfill 420 may fill spaces between the Si interposer 400 and the package substrate 100a and between inter-substrate connection terminals 320. The Si interposer 400 may be substantially identical to the Si bridge interposer 130 in the semiconductor package 1000 of FIG. 1 in terms of the function and the structure, except for the size and the position. Therefore, the Si interposer 400 may include a plurality of via electrodes therein and may connect the at least two semiconductor devices 210 of the package upper structure 200d to each other.

The package upper structure 200d may include the at least two semiconductor devices 210, the upper connection terminal 220, the underfill 230, and the sealing member 260. The at least two semiconductor devices 210 may be stacked on the Si interposer 400 through the upper connection terminals 220. The underfill 230 may fill spaces between the at least two semiconductor devices 210 and the Si interposer 400 and between the upper connection terminals 220. The sealing member 260 may cover and seal the at least two semiconductor devices 210 on the Si interposer 400 and the underfill 230. According to some embodiments, like the package upper structure 200a of the semiconductor package 1000a of FIG. 5A, the underfill 230 may be omitted and the spaces between at least two semiconductor devices 210 and the Si interposer 400 and between the upper connection terminals 220 may be filled with the sealing member 260.

FIGS. 7A to 7F are schematic plan views of operations of a method of manufacturing a semiconductor package, according to an embodiment. Descriptions are given below with reference to FIG. 1, and descriptions already given above with reference to FIGS. 1 to 5C are briefly given or omitted.

Referring to FIG. 7A, in the method of manufacturing a semiconductor package according to the present embodiment, first, a panel-sized frame FR is prepared. Here, a panel size may correspond to a combined size of a plurality of package substrates. The frame FR may include a plurality of rectangular lattices, e.g., frame grids FRg each having a rectangular ring-like shape. As shown in FIG. 7A, the frame grids FRg may each have a ring-like shape.

Referring to FIG. 7B, after the frame FR is prepared, a tape TA is attached to the bottom surface of the frame FR. The tape TA may have a size that covers the entire frame FR. FIG. 7B shows the top surface of the frame FR, and the tape TA may be attached on the bottom surface of the frame FR. Therefore, the tape TA may cover bottom surfaces of the frame grids FRg. Also, a portion of the tape TA may be covered in a rectangular ring-like shape by the frame grids FRg. Hereinafter, for convenience of explanation, descriptions will be given based on a single frame grid FRg.

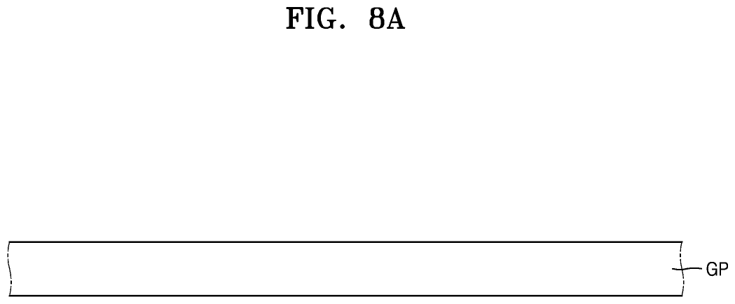

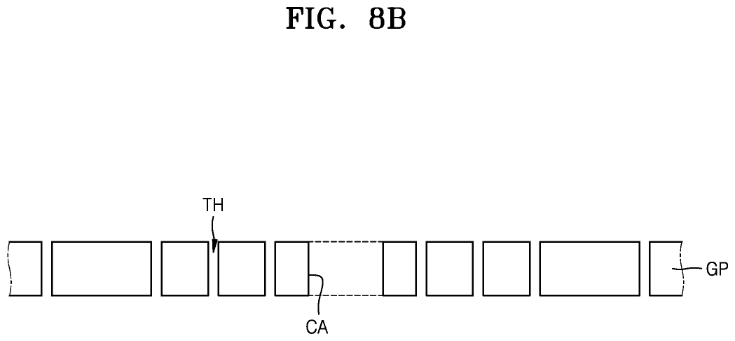

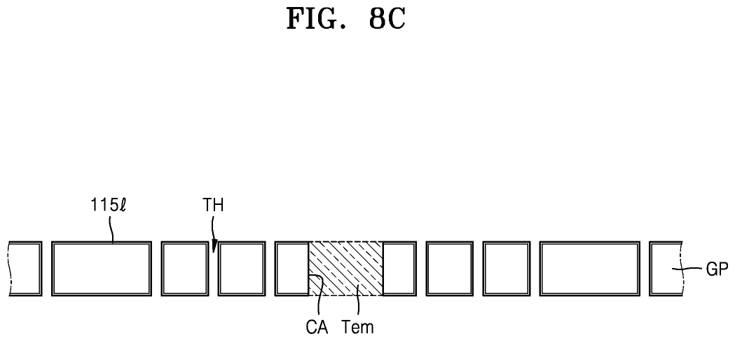

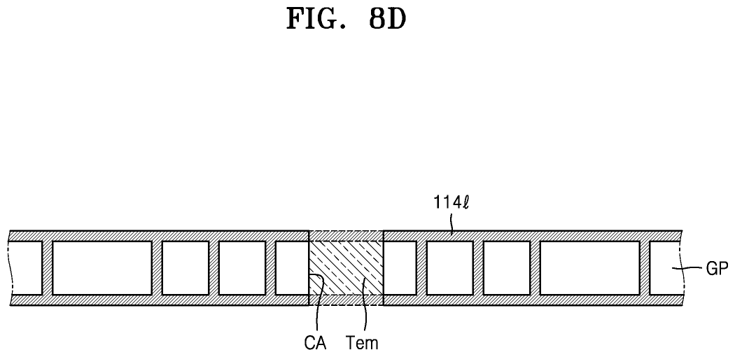

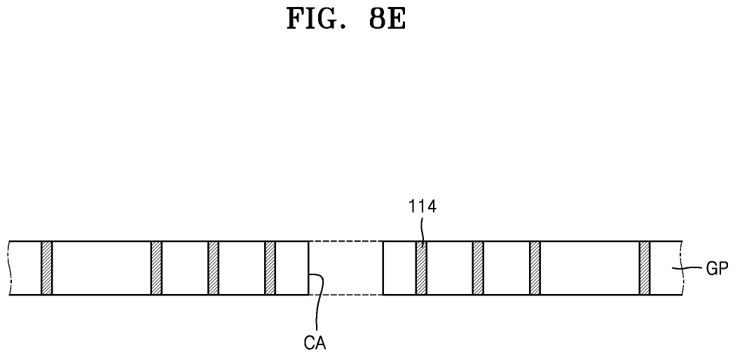

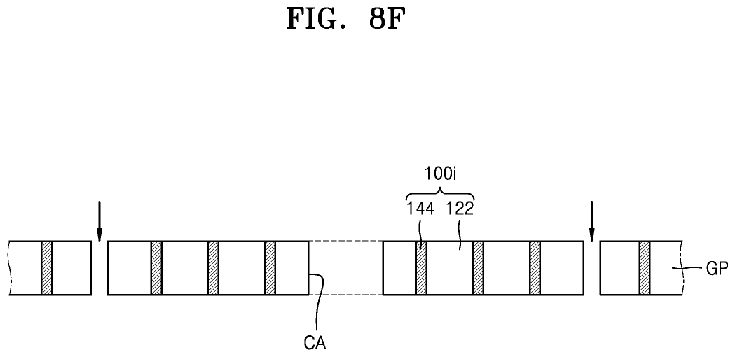

Referring to FIG. 7C, an initial glass core substrate 110i is disposed within the frame grid FRg. For example, the top surface of the initial glass core substrate 110i is attached to a portion of the tape TA within the frame grid FRg. As shown in FIG. 7C, the planar area of the initial glass core substrate 110i may be smaller than the inner planar area of the frame grid FRg. Therefore, the tape TA may be exposed to the outside of the initial glass core substrate 110i and to the cavity CA. For reference, the portion shown in FIG. 7C may correspond to the bottom surface of the glass core substrate 110 in FIG. 2B or 2C. Meanwhile, the initial glass core substrate 110i may refer to a substrate in which the vias 117, the glass pads 116, and the protective layer 118 are not formed. A method of manufacturing the initial glass core substrate 110i will be described below in more detail in the description of FIGS. 8A to 8F.

Referring to FIG. 7D, the Si bridge interposer 130 is subsequently disposed inside the cavity CA of the initial glass core substrate 110i. For example, the top surface of the Si bridge interposer 130 is attached to a portion of the tape TA in the cavity CA.

Referring to FIG. 7E, after the Si bridge interposer 130 is disposed, an ABF resin 122a is laminated on the bottom surface of the initial glass core substrate 110i and the Si bridge interposer 130. For example, the ABF resin 122a may be laminated on the bottom surfaces of the initial glass core substrate 110i and the Si bridge interposer 130 while applying heat and pressure thereto. Through the process of laminating the ABF resin 122a, the bottom surfaces of the initial glass core substrate 110i and the Si bridge interposer 130 may be covered by the ABF resin 122a, and side surfaces of the initial glass core substrate 110i may be covered by the ABF resin 122a. Also, the space between the initial glass core substrate 110i and the Si bridge interposer 130 may be filled with the ABF resin 122a.

Referring to FIG. 7F, a plurality of open holes are subsequently formed in the ABF resin 122a, thereby exposing the bottom surfaces of the via electrodes 114 of the initial glass core substrate 110i and the bottom surfaces of the via electrodes 134 of the Si bridge interposer 130. A process of forming the open holes in the ABF resin 122a may be performed through a laser drilling process or an etching process. Meanwhile, relatively large open holes may be formed to facilitate alignment and coupling between via electrodes 114 and 134 and pads 116 and 136. For example, the bottoms of the open holes may be larger than the bottom surface of the via electrodes 114 and 134, and thus the entire bottom surfaces of the via electrodes 114 and 134 may be exposed through the bottoms of the open holes.

Thereafter, the vias 117 and the glass pads 116 are formed in the open holes. The vias 117 and the glass pads 116 may be formed through, for example, an electroplating process. The vias 117 and the glass pads 116 may have shapes as shown in FIG. 2C. For example, the vias 117 may have a trapezoidal vertical cross-section, and the top surface of the vias 117 may be larger than the bottom surfaces of the via electrodes 114 and 134. Also, the glass pads 116 are disposed on the bottom surface of the vias 117 and may have a circular or rectangular flat panel-like shape. Since the portion shown in FIG. 7F corresponds to the bottom surface of the glass core substrate 110 in FIG. 2B or 2C, the vias 117 and the glass pads 116 may correspond to the lower vias 117d and the lower glass pads 116d, respectively.

Thereafter, multi-layered wiring lines 124 are formed by building up the ABF resin 122a. Therefore, the ABF resin 122a may constitute the protective layer 118 of the glass core substrate 110 and may also constitute the insulation body 122 of the package substrate 100. The package substrate 100 may be completed by forming the multi-layered wiring lines 124 by using the ABF resin 122a.

Subsequently, the top surfaces of the initial glass core substrate 110i and the Si bridge interposer 130 are exposed by removing the tape TA. Thereafter, an ABF resin lamination process is performed on the top surfaces of the glass core substrate 110 and the Si bridge interposer 130, open holes are formed in an ABF resin, and the vias 117 and the glass pads 116 are formed in the open holes. Here, the vias 117 and the glass pads 116 may correspond to the upper vias 117u and the upper glass pads 116u, respectively. Through the formation of the upper vias 117u and the upper glass pads 116u, the glass core substrate 110 may be completed. Thereafter, at least two semiconductor devices may be stacked on the glass pads 116, and a sawing process may be performed along a cutting line CL, thereby completing an individual semiconductor package 1000 of FIG. 1.

Meanwhile, a process of forming the substrate protection layer 129 and the external connection terminal 300 on the bottom surface of the package substrate 100 may be performed before removing the tape TA. Also, according to some embodiments, after individual semiconductor packages 1000 are completed, the substrate protection layer 129 and the external connection terminal 300 may be formed for each of the individual semiconductor package 1000.

FIGS. 8A to 8F are schematic cross-sectional views of operations of manufacturing a glass core substrate in the method of manufacturing a semiconductor package of FIGS. 7A to 7F. Descriptions are given below with reference to FIG. 1, and descriptions already given above with reference to FIGS. 1 to 5C are briefly given or omitted.

Referring to FIG. 8A, first, a glass panel GP is prepared. The glass panel GP may have a size capable of including a plurality of glass core substrates. Therefore, the glass panel GP may be individualized into a plurality of unit glass core substrates after completion of an initial glass core substrate.

Referring to FIG. 8B, a plurality of through holes TH for forming via electrodes are formed in the glass panel GP. Also, in the process of forming the through holes TH, the cavity CA is formed in a portion of the glass panel GP corresponding to the central portion of a glass core substrate. The through holes TH and the cavity CA may be formed through a laser drilling process or an etching process. However, the process of forming the through holes TH and the cavity CA is not limited to the above-stated processes. Meanwhile, according to some embodiments, the through holes TH and the cavity CA may be formed in different operations. For example, the cavity CA may be formed after the via electrode 114 of FIG. 8E is formed.

Referring to FIG. 8C, an adhesive layer 1151 is formed on the glass panel GP. The adhesive layer 1151 may be formed inside the through holes TH and on the top surface and the bottom surface of the glass panel GP. Meanwhile, an anti-adhesive layer Tem may be disposed inside the cavity CA to prevent formation of the adhesive layer 1151 in the cavity CA. The adhesive layer 1151 may be a conductive layer or a non-conductive layer. For example, the adhesive layer 1151 may include or be a metal layer.

Referring to FIG. 8D, after the adhesive layer 1151 is formed, a metal layer 1141 for a via electrode is formed. For example, a Cu layer is formed on the adhesive layer 1151 through electroplating. On the other hand, when the adhesive layer 1151 is not a metal layer, a process of forming a separate seed metal layer may precede the process of forming the metal layer 1141 for the via electrode. The via electrode metal layer 1141 may fill the through holes TH and be formed on the top surface and the bottom surface of the glass panel GP. Meanwhile, due to the anti-adhesive layer Tem, the metal layer 1141 for a via electrode may not be formed inside the cavity CA.

Referring to FIG. 8E, subsequently, through a grinding process and/or a polishing process, portions of the metal layer 1141 for a via electrode on the top surface and the bottom surface of the glass panel GP are removed, thereby forming the via electrodes 114 inside the through holes TH. Thereafter, the anti-adhesive layer Tem inside the cavity CA is removed. When the cavity CA is not formed in the previous process as described above, after the via electrode 114 is formed, the cavity CA may be formed at a portion of the glass panel GP corresponding to the central portion of a glass core substrate. Through the formation of the via electrodes 114, a plurality of initial glass core substrates 100i may be completed in the glass panel GP.

Referring to FIG. 8F, subsequently, as indicated by arrows, the initial glass core substrates 100i are completed by individualizing the initial glass core substrates 100i through a sawing process.

While the inventive concept has been particularly shown and described with reference to embodiments thereof, it will be understood that various changes in form and details may be made therein without departing from the spirit and scope of the following claims.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

1. A semiconductor package comprising:
a package substrate comprising a glass core substrate, a semiconductor bridge interposer, and a multi-layer wiring layer disposed under the glass core substrate and the semiconductor bridge interposer; and
at least two semiconductor devices stacked on the package substrate,
wherein a cavity is formed in a central portion of the glass core substrate, and the semiconductor bridge interposer is embedded in the cavity.

2. The semiconductor package of claim 1, wherein the glass core substrate comprises a glass body having formed therein the cavity, via electrodes penetrating through the glass body, and upper pads and lower pads respectively on a top surface and a bottom surface of the glass body, and
the via electrodes respectively connect the upper pads and the lower pads to each other.

3. The semiconductor package of claim 2, wherein each via electrode comprises a metal electrode layer extending between a respective upper pad and a respective lower pad and an adhesive layer surrounding the metal electrode layer.

4. The semiconductor package of claim 2, wherein the glass core substrate further comprises a protective layer surrounding an outer surface of the glass body, and
each upper pad and respective lower pad are connected to a respective via electrode through a respective via penetrating through the protective layer.

5. The semiconductor package of claim 4, wherein a vertical cross-section of each via has a trapezoidal structure in which a portion connected to the via electrode is relatively narrow and a portion connected to the respective upper pad or the lower pad is relatively wide.

6. The semiconductor package of claim 4, wherein a horizontal cross-section of each via is larger than a horizontal cross-section of each via electrode, and, at a junction between each via and each respective via electrode, a horizontal distance between an end of the via and an end of the via electrode is from about 5 μm to about 30 μm.

7. The semiconductor package of claim 4, wherein the glass core substrate further comprises a seed layer disposed between each via electrode and each respective via.

8. The semiconductor package of claim 4, wherein the protective layer is entirely formed of the same material or at least a portion thereof is formed of a different material, and a distinct interface is formed in at least a portion of the protective layer.

9. The semiconductor package of claim 1, wherein the semiconductor bridge interposer connects the at least two semiconductor devices to each other, and
each of the at least two semiconductor devices comprises a logic chip or a memory chip.

10. The semiconductor package of claim 9, wherein any one of the at least two semiconductor devices has a package structure comprising a plurality of memory chips.

11. The semiconductor package of claim 1, wherein the at least two semiconductor devices are stacked on the package substrate in a single package structure or each of the at least two semiconductor devices is stacked on the package substrate as a separate structure.

12. The semiconductor package of claim 1, wherein the glass core substrate is disposed in an asymmetrical structure in a vertical direction within the package substrate.

13. A semiconductor package comprising:
a package substrate comprising a glass core substrate and a multi-layer wiring layer disposed on at least one of a bottom surface and a top surface of the glass core substrate;
a semiconductor interposer disposed on the package substrate; and
at least two semiconductor devices arranged on the semiconductor interposer.

14. The semiconductor package of claim 13, wherein a cavity is formed in a central portion of the glass core substrate, and
the semiconductor package further comprises a passive device disposed in the cavity.

15. The semiconductor package of claim 13, wherein the glass core substrate is disposed in a central portion of the package substrate in a vertical direction, and
the package substrate comprises an upper multi-layer wiring layer disposed on the top surface of the glass core substrate and a lower multi-layer wiring layer disposed on the bottom surface of the glass core substrate.

16. The semiconductor package of claim 13, wherein the glass core substrate comprises a glass body, in which a cavity is formed in a central portion, via electrodes penetrating through the glass body, and upper pads and lower pads respectively on a top surface and a bottom surface of the glass body, and
the vias electrode connect the upper pads and the lower pads to each other.

17. The semiconductor package of claim 16, wherein the glass core substrate further comprises a protective layer surrounding an outer surface of the glass body, and
the upper pads and the lower pads are connected to the via electrodes through respective vias penetrating through the protective layer.

18. The semiconductor package of claim 17, wherein a horizontal cross-section of each via is larger than a horizontal cross-section of each via electrode,
a vertical cross-section of each via has a trapezoidal structure in which a portion connected to a respective via electrode is narrow and a portion connected to a respective upper pad or lower pad is wide.

19. The semiconductor package of claim 17, wherein the semiconductor interposer connects the at least two semiconductor devices to each other, and
each of the at least two semiconductor devices comprises a logic chip or a memory chip.

20. A semiconductor package comprising:
a package substrate comprising a glass core substrate and a multi-layer wiring layer disposed on at least one of a bottom surface and a top surface of the glass core substrate;
a semiconductor interposer disposed within the package substrate or disposed on a top surface of the package substrate; and
at least two semiconductor devices arranged on the package substrate or the semiconductor interposer,
wherein:
a cavity is formed in a central portion of the glass core substrate, when the semiconductor interposer is disposed within the package substrate, the semiconductor interposer is disposed in the cavity, and,
when the semiconductor interposer is disposed on the top surface of the package substrate, a passive device is disposed in the cavity.

21-25. (canceled)
